(19) United States
(12) Patent Application Publication
(10) Pub. No.: US 2009/0134487 A1
(43) Pub. Date: May 28, 2009

(54) IMAGE SENSOR AND METHOD FOR MANUFACTURING THE SAME

(76) Inventor: Tae-Gyu Kim, Masan-si (KR)

Correspondence Address: SHERR & VAUGHN, PLLC, 620 HERNDON PARKWAY, SUITE 200, HERNDON, VA, 20170, US

(21) Appl. No.: 12/323,032

(22) Filed: Nov. 25, 2008

(30) Foreign Application Priority Data
Nov. 27, 2007 (KR) 10-2007-0121252

(51) Int. Cl. H01L 31/102; H01L 21/18

(52) U.S. Cl. 257/461; 438/98; 257/E31.055; 257/E21.087

(57) ABSTRACT

An image sensor includes a first substrate, a lower metal line, a circuitry, a first insulating layer, a crystalline semiconductor layer, a photodiode, and a contact line. The lower metal line and the circuitry are formed on and/or over the first substrate and the first insulating layer is formed on and/or over the lower metal line. The crystalline semiconductor layer contacts the first insulating layer and is bonded to the first substrate. The photodiode is formed in the crystalline semiconductor layer. The contact line electrically connects the photodiode to the lower metal line.

The present application claims under 35 U.S.C. §119 to Korean Patent Application No. 10-2007-0121252 (filed Nov. 27, 2007), which is hereby incorporated by reference in its entirety.

### BACKGROUND

An image sensor is a semiconductor device for converting an optical image into an electric signal. The image sensor may be classified into a charge coupled device (CCD) image sensor and a complementary metal oxide silicon (CMOS) image sensor (CIS). A CIS includes a photodiode and a MOS transistor formed in a unit pixel, and obtains an image by sequentially detecting electrical signals of unit pixels in a switching manner. In a related art CIS structure, a photodiode and a transistor may be horizontally arranged. Although the related art horizontal-type CIS has solved the limitations of CCD image sensors, it still has several problems. For instance, because in a horizontal-type CIS a photodiode and a transistor are horizontally formed adjacent to each other on and/or over a substrate, an additional region for forming the photodiode is required. Accordingly, a decrease in the fill factor may result and limit the possibility of resolution. Also, in the horizontal-type CIS according to the related art, it is difficult to achieve the optimized process of concurrently forming the photodiode and the transistor.

### SUMMARY

Embodiments relate to an image sensor and a manufacturing method thereof that provide a new integration of circuitry and a photodiode.

Embodiments relates to an image sensor and a manufacturing method thereof using a crystal silicon bonding process to secure a process margin by performing bonding easily and also easily secure ohmic contact between a lower metal and crystal silicon in forming a contact.

Embodiments relate to an image sensor and a manufacturing method thereof that maximizes resolution and sensitivity.

Embodiments relate to an image sensor and a manufacturing method thereof that employs a vertical-type photodiode that prevents generation of a defect therein.

Embodiments relate to an image sensor that may include at least one of the following: a first substrate on and/or over which a lower metal line and a circuitry are formed; a first insulating layer formed on and/or over the lower metal line; a crystalline semiconductor layer contacting the first insulating layer and bonded to the first substrate; a photodiode formed in the crystalline semiconductor layer; and a contact line electrically connecting the photodiode to the lower metal line.

Embodiments relate to a device that may include at least one of the following: a first substrate;a lower metal line and circuitry formed over the first substrate; a first insulating layer formed over the lower metal line;a crystalline semiconductor layer contacting the first insulating layer and bonded to the first substrate; a photodiode formed in the crystalline semiconductor layer; and a contact line electrically connecting the photodiode to the lower metal line.

Embodiments relate to a method that may include at least one of the following: providing a first substrate over which a lower metal line and a circuitry are formed; and then forming a first insulating layer over the lower metal line of the first substrate; and then providing a second substrate over which a photodiode is formed; and then bonding the second substrate to the first substrate such that the photodiode of the second substrate contacts the first insulating layer of the first substrate; and then exposing the photodiode by removing a lower portion of the second substrate.

Embodiments relate to a method for manufacturing an image sensor that may include at least one of the following: providing a first substrate on and/or over which a lower metal line and a circuitry are formed; forming a first insulating layer on and/or over the lower metal line of the first substrate; providing a second substrate on and/or over which a photodiode is formed; bonding the second substrate to the first substrate such that the photodiode of the second substrate contacts the first insulating layer of the first substrate; and then exposing the photodiode by removing a lower portion of the second substrate.

### DRAWINGS

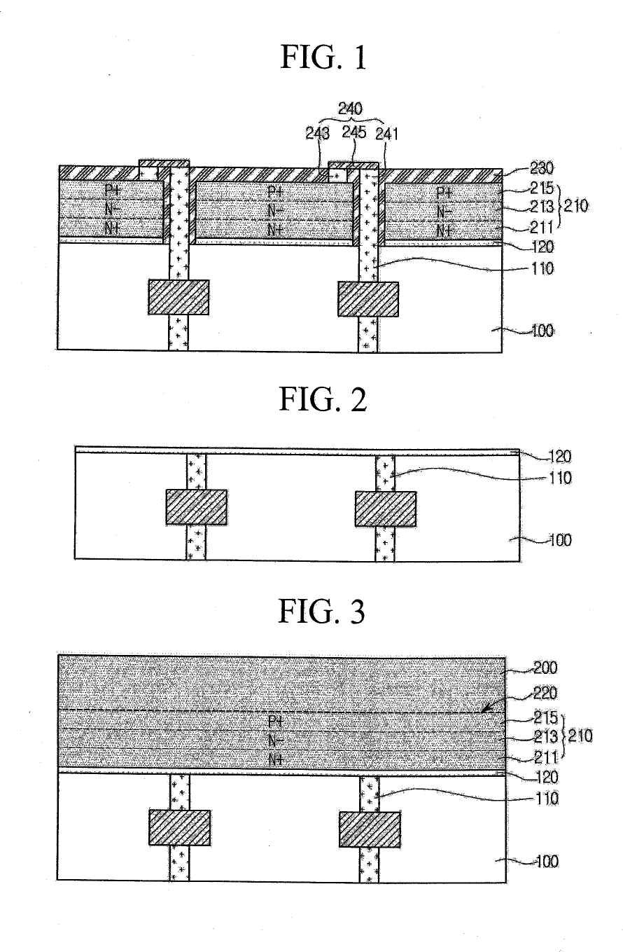

Example FIGS. 1 to 10 illustrate an image sensor and a method for manufacturing an image sensor in accordance with embodiments.

### DESCRIPTION

An image sensor and a method for manufacturing an image sensor in accordance with embodiments will be described in detail with reference to the accompanying drawings.

As illustrated in example FIG. 1, an image sensor in accordance with embodiments can include first substrate 100 on and/or over which lower metal line 110 and circuitry are formed; first insulating layer 120 formed on and/or over lower metal line 110; crystalline semiconductor layer 210 contacting first insulating layer 120 and bonded to first substrate 100; photodiode 210 formed in crystalline semiconductor layer 210; and contact line 240 electrically connecting lower metal line 110 to photodiode 210.

In embodiments, photodiode 210 can include first conductive type conduction layer 213 formed in crystalline semiconductor layer 210 and second conductive type conduction layer 215 formed in crystalline semiconductor layer 210 on and/or over first conductive type conduction layer 213. Alternatively, photodiode 210 may further include high concentration first conduction type conduction layer 211 formed in crystalline semiconductor layer 210 under first conduction type conduction layer 213.

An image sensor in accordance with embodiments can further include second insulating layer 230 formed on and/or over crystalline semiconductor layer 210 and including second trench T2 (see example FIG. 8) selectively exposing lower metal line 110 and third trench T3 (see example FIG. 8) selectively exposing photodiode 210. Contact line 230 can include second plug 241 and third plug 243 filling second trench T2 and third trench T3, respectively and metal line 245 connecting second plug 241 to third plug 243. Second plug 241 can act as a bias contact, and third plug 243 can act as a signal contact.

Second trench T2 may be formed by etching second insulating layer 230 such that lower metal line 110 is exposed but photodiode 210 is not exposed. Thus, second plug T2 in accordance with embodiments can be formed in a device isolation region. The image sensor in accordance with embodiments can provide a vertical integration of circuitry and photodiode. Also, the image sensor in accordance with embodiments can maximize a bonding force between first substrate 100 and a second substrate by forming insulating layer 120 such as oxide layer on and/or over first substrate 100 prior to bonding second substrate 200 to an uppermost surface of first substrate 100. Further, the image sensor in accordance with embodiments can further maximize bonding and cleaving states by forming insulating layer 120 on and/or over first substrate 100 prior to bonding second substrate 200 to an uppermost surface of first substrate 100 to thereby minimize a height difference due to a CMP or the like. Moreover, the image sensor according to embodiments can obtain enhanced characteristics in forming ohmic contact between the lower metal line of first substrate 100 and second substrate 200.

As illustrated in example FIGS. 2 to 10, a method for manufacturing an image sensor in accordance with embodiments may include providing first substrate 100 in which lower metal line 110 and circuitry are formed. The image sensor in accordance with embodiments may be a CIS that can be but is not limited to a four transistor CIS. Thereafter, first insulating layer 120 is formed on and/or over lower metal line 110 of first substrate 100. For example, first insulating layer 120 can be but is not limited to an oxide layer. The forming of first insulating layer 120 can enhance a bonding force between first substrate 100 and a substrate to be bonded to first substrate 100.

As illustrated in example FIG. 3, next, second substrate 200 in which photodiode 210 is formed is prepared and is bonded to first substrate 100. The preparing of second substrate 200 will now be described in more detail. First, crystalline semiconductor layer 210 is formed on and/or over second substrate 200. Photodiode 210 is formed in crystalline semiconductor layer 210, so that a defect inside the photodiode can be prevented.

The preparing of second substrate 200 may be performed as follows. For example, hydrogen ion implantation layer 220 is first formed by implanting hydrogen ions into second substrate 200. Thereafter, impurity ions are implanted into crystalline semiconductor layer 210 to form photodiode 210. Alternatively, a buried insulating layer may be first formed in second substrate 200, and then crystalline semiconductor layer 210 may be formed on and/or over second substrate 200. For example, buried insulating layer can be but is not limited to a Silicon-On-Insulator (SOI).

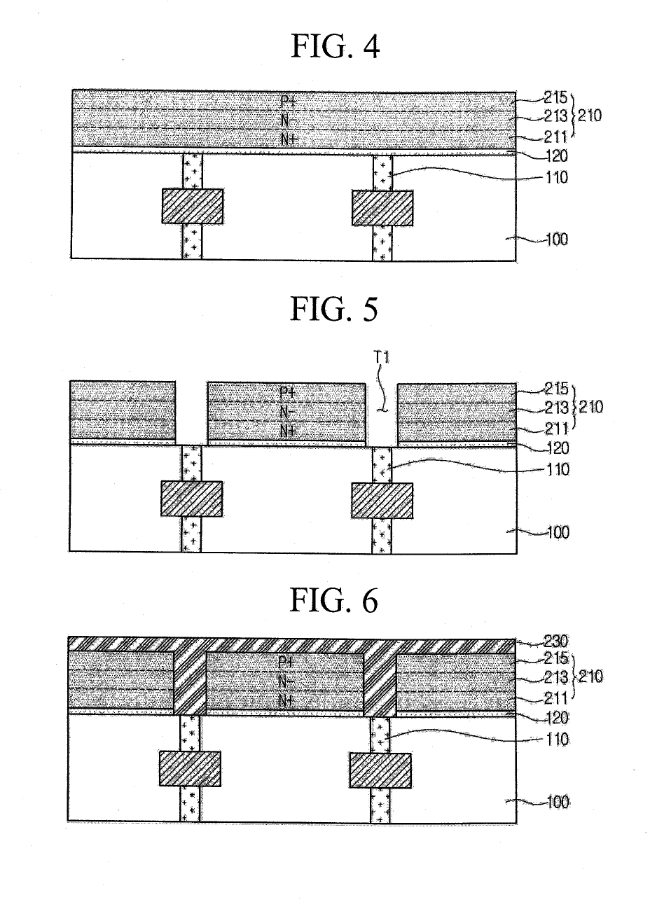

As illustrated in example FIG. 4, a process of forming photodiode 210 includes forming photodiode 210 in crystalline semiconductor layer 210 using ion implantation. For example, second conduction type conduction layer 215 is formed in the lower portion of crystalline semiconductor layer 210. Second conduction type conduction layer 215 can be a high concentration P-type conduction layer. For example, high concentration P-type conduction layer 215 can be formed in the lower portion of crystalline semiconductor layer 210 by performing a first blanket-ion implantation onto the entire surface of second substrate 200 without a mask. For example, second conduction type conduction layer 215 can be formed at a junction depth of less than about 0.5 μm.

After that, first conduction type conduction layer 213 is formed on and/or over second conduction type conduction layer 215 by performing a second blanket-ion implantation on the entire surface of second substrate 200 without a mask. First conduction type conduction layer 213 can be a low concentration N-type conduction layer. Low concentration first conduction type conduction layer 213 can be formed at a junction depth ranging from about 1.0 μm to about 0.5 μm.

As illustrated in FIG. 3, embodiments may further include forming high concentration first conduction type conduction layer 211 on and/or over first conduction type conduction layer 213. High concentration first conduction type conduction layer 211 can be a high concentration N-type conduction layer. For example, high concentration first conduction type conduction layer 211 can be formed on and/or over first conduction type conduction layer 213 by performing a third blanket-ion implantation onto the entire surface of second substrate 200 without a mask. High concentration first conduction type conduction layer 211 can be formed at a junction depth in a range between approximately 0.05 μm to 0.2 μm. As illustrated in example FIG. 3, first substrate 100 and second substrate 200 are then bonded such that photodiode 210 of second substrate 200 contacts first insulating layer 120 of first substrate 100. For example, the bonding may be performed by contacting first substrate 100 and second substrate 200 to each other and then performing activation by plasma, but is not limited thereto.

As illustrated in example FIG. 4, after that, a lower portion of second substrate 200 is removed to leave photodiode 210. For example, hydrogen ion implantation layer 220 as formed in second substrate 200 can be changed into a hydrogen gas layer by performing heat treatment on second substrate 200. A lower portion of second substrate 200 can be easily removed about hydrogen gas layer such that photodiode 210 can be exposed. In another embodiments, when second substrate 200 has buried insulating layer, a lower portion of second substrate is removed by back grinding to expose buried insulating layer, and exposed buried insulating layer is then removed by etching to leave only photodiode 210 on first substrate 100, as illustrated in FIG. 4. For example, buried insulating layer can be removed by wet etch, but the present invention is not limited thereto.

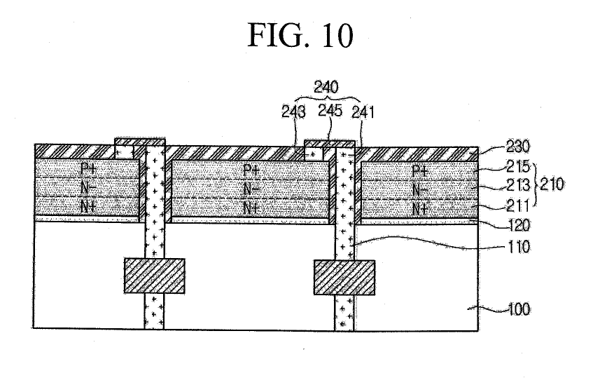

As illustrated in example FIG. 5, after the exposing of photodiode 210, photodiode 210 and first insulating layer 120 are selectively etched to form first trench Ti so that lower metal line 110 is exposed. After that, as illustrated in example FIG. 10, contact line 240 electrically connecting photodiode 210 to lower metal line 110 can be formed.

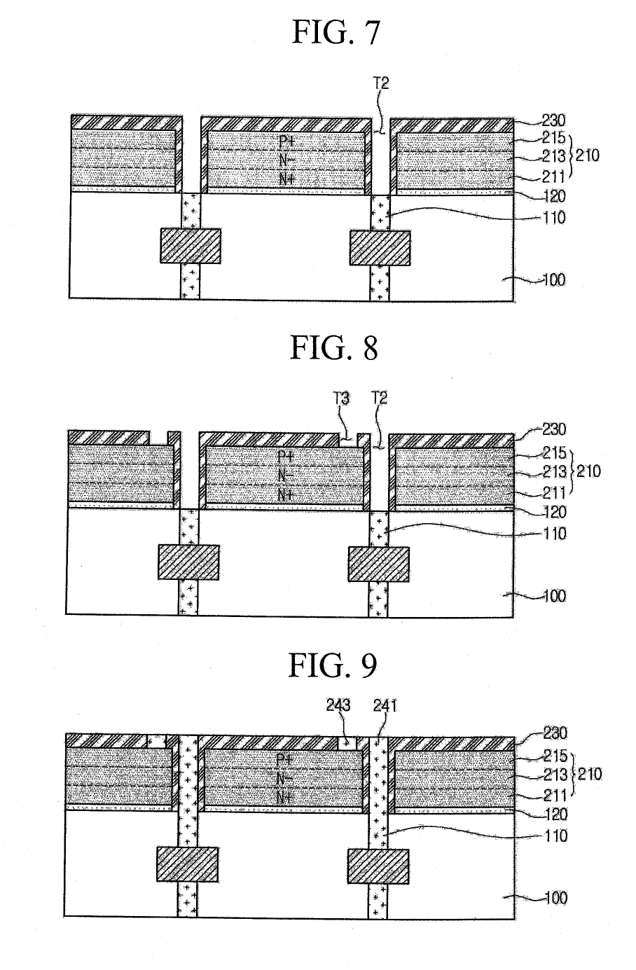

As illustrated in example FIG. 6, a process of forming contact line 240 can include forming second insulating layer 230 on and/or over first trench Ti and photodiode 210. Second insulating layer 230 can be but is not limited to an oxide layer. As illustrated in example FIG. 7, next, second insulating layer 230 is selectively etched to form second trench T2 so that lower metal line 110 is exposed. The etching of second insulating layer 230 may correspond to bias contact etch. Second insulating layer 230 can be etched so as not to etch photodiode 210 so that second insulating layer 230 is interposed between photodiodes of respective pixels to prevent crosstalk between pixels.

As illustrated in example FIG. 8, next, second insulating layer 230 is selectively etched to form third trench T3 so that photodiode 210 is selectively exposed. The selective etching of second insulating layer 230 may correspond to a signal contact etch. As illustrated in example FIG. 9, next, second plug 241 and third plug 243 filling second trench T2 and third trench T3, respectively can be formed. Second plug 241 and third plug 243 can be formed of tungsten, but the present invention is not limited thereto. Second plug 241 acts as a bias contact, and third plug 243 acts as a signal contact. As illustrated in example FIG. 10, next, metal line 245 connecting second plug 241 and third plug 243 to each other can be formed. Metal line 245 can be formed of aluminum (Al), copper (Cu) or the like, but the present invention is not limited thereto.

The image sensor and the manufacturing method thereof in accordance with embodiments can provide vertical integration of circuitry and photodiode. Also, the image sensor and the manufacturing method thereof in accordance with embodiments can maximize a bonding force between first substrate and second substrate by forming insulating layer such as oxide layer on and/or over first substrate prior to bonding second substrate to upper surface of first substrate. Further, the image sensor and the manufacturing method thereof in accordance with embodiments can further improve bonding and cleaving states by forming insulating layer on and/or over first substrate prior to bonding second substrate to upper surface of first substrate to thereby minimize a height difference due to a CMP or the like. Moreover, the image sensor and the manufacturing method thereof according to embodiments are expected to obtain enhanced characteristics in forming ohmic contact between lower metal line of first substrate and second substrate.

Although embodiments relate generally to a complementary metal oxide semiconductor (CMOS) image sensor, such embodiments are not limited to the same and may be readily applied to any image sensor requiring a photodiode.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a first substrate;
a lower metal line and circuitry formed over the first substrate;
a first insulating layer formed over the lower metal line;
a crystalline semiconductor layer contacting the first insulating layer and bonded to the first substrate;
a photodiode formed in the crystalline semiconductor layer; and
a contact line electrically connecting the photodiode to the lower metal line.

2. The device of claim 1, wherein the photodiode comprises:
a high concentration first conduction type conduction layer formed in the crystalline semiconductor layer;
a first conduction type conduction layer formed in the crystalline semiconductor layer over the high concentration first conduction type conduction layer; and
a second conduction type conduction layer formed in the crystalline semiconductor layer over the first conduction type conduction layer.

3. The device of claim 1, wherein the photodiode comprises a high concentration first conduction type conduction layer formed in the crystalline semiconductor layer.

4. The device of claim 1, wherein the photodiode comprises a first conduction type conduction layer formed in the crystalline semiconductor layer.

5. The device of claim 4, wherein the photodiode comprises a second conduction type conduction layer formed in the crystalline semiconductor layer over the first conduction type conduction layer.

6. The device of claim 4, wherein the photodiode further comprises a high concentration first conduction type conduction layer formed in the crystalline semiconductor layer under the first conduction type conduction layer.

7. The device of claim 1, further comprising a second insulating layer formed in the crystalline semiconductor layer and including a second trench selectively exposing the lower metal line and a third trench exposing the photodiode.

8. The device of claim 7, wherein the contact line comprises:
a second plug filling the second trench;
a third plug filling the third trench; and
a metal line connecting the second plug to the third plug.

9. The device of claim 7, wherein the second trench exposes the lower metal line but does not expose the photodiode.

10. The device of claim 7, wherein the second plug is formed in a device isolation region.

11. The device of claim 1, wherein the device comprises an image sensor.

12. A method comprising:
providing a first substrate over which a lower metal line and a circuitry are formed; and then
forming a first insulating layer over the lower metal line of the first substrate; and then
providing a second substrate over which a photodiode is formed; and then
bonding the second substrate to the first substrate such that the photodiode of the second substrate contacts the first insulating layer of the first substrate; and then
exposing the photodiode by removing a lower portion of the second substrate.

13. The method of claim 12, further comprising, after the exposing of the photodiode:
forming a first trench exposing the lower metal line by selectively etching the photodiode and the first insulating layer; and then
forming a contact line electrically connecting the lower metal line to the photodiode.

14. The method of claim 13, wherein forming the contact line comprises:
forming a second insulating layer over the first trench and the photodiode; and then
forming a second trench exposing the lower metal line by selectively etching the second insulating layer; and then
selectively exposing the photodiode by selectively etching the second insulating layer to form a third trench; and then
forming a second plug and a third plug filling the second trench and the third trench, respectively; and then
forming a metal line connecting the second plug to the third plug.

15. The method of claim 14, wherein forming the second trench comprises etching the second insulating layer such that the photodiode is not exposed.

16. The device of claim 12, wherein the photodiode comprises a high concentration first conduction type conduction layer formed in a crystalline semiconductor layer.

17. The device of claim 12, wherein the photodiode comprises a first conduction type conduction layer formed in a crystalline semiconductor layer.

18. The device of claim 17, wherein the photodiode comprises a second conduction type conduction layer formed in the crystalline semiconductor layer over the first conduction type conduction layer.

19. The device of claim 12, wherein the photodiode further comprises a high concentration first conduction type conduction layer formed in the crystalline semiconductor layer under the first conduction type conduction layer.

20. The device of claim 12, wherein the photodiode comprises:
a high concentration first conduction type conduction layer formed in the crystalline semiconductor layer;
a first conduction type conduction layer formed in the crystalline semiconductor layer over the high concentration first conduction type conduction layer; and
a second conduction type conduction layer formed in the crystalline semiconductor layer over the first conduction type conduction layer.
